(19) United States
(12) Patent Application Publication
(10) Pub. No.: US 2023/0304830 A1
(43) Pub. Date: Sep. 28, 2023

(54) LOW-COST COMPACT MICRO-DISPLACEMENT SENSOR

(71) Applicant: National Tsing Hua University, Hsinchu (TW)

(72) Inventors: Che-Chih Tsao, Hsinchu (TW); Yi-Chun Tseng, Hsinchu (TW)

(73) Assignee: National Tsing Hua University, Hsinchu (TW)

(21) Appl. No.: 18/129,184

(22) Filed: Mar. 31, 2023

Related U.S. Application Data
(63) Continuation-in-part of application No. 16/677,174, filed on Nov. 7, 2019, now abandoned.
(60) Provisional application No. 62/756,730, filed on Nov. 7, 2018.

(51) Int. Cl. G01D 5/14; G01R 33/07

(52) U.S. Cl. CPC G01D 5/147; G01R 33/072

(57) ABSTRACT

This invention describes a small sized precision displacement sensor at sub-micron accuracy level with a cost of a fraction of those of existing commercial devices. The basic concept of the new sensor system is to apply a mechanical mechanism to magnify a sub-micron displacement to be measured so that the magnified displacement becomes within the measurement range of a low cost sensor such as a Hall sensor.

### CROSS-REFERENCE TO RELATED APPLICATION

This application is a Continuation-in-Part of U.S. patent application Ser. No. 16/677,174 filed on Nov. 7, 2019, which claims the benefit of U.S. Provisional Patent Application No. 62/756,730 filed on Nov. 7, 2018. The contents of the above-identified applications are incorporated by reference in their entirety.

### BACKGROUND OF THE INVENTION

### 1. Field of the Invention

The present invention relates to a precision micro-displacement sensor of compact, small characteristic size, simple construction and low cost.

### 2. Background

Precision displacement sensors or gauges are useful in measurements and checking of dimensions of manufactured parts, positions of machine stages, assembly precisions of components in a machine system and in other areas. Traditional mechanical displacement gauges such as dial indicator or meter based on gears and spiral spring have a precision of about 2 μm (micron, or micro meter) and are not suitable for readings resolved down to sub-micron level. Although highly precise displacement measurement systems such as interferometers can easily make sub-micron measurements, they are extremely expensive and bulky and generally not suitable for in-process or in-machine applications. For in-process, in-machine precision measurements, there are several existing devices available for use, as shown in the table of FIG. 1. Among these devices, capacitive sensor, eddy current sensor and digital contact sensor (from Keyence, a contact-type mechanical sensor with a built-in digital optical sensor) can reach 1 micron accuracy and sub-micron resolution. But they are still expensive. The table shows the price of a single sensor head in USD.

If a small sized displacement sensor of comparable precision and resolution can be obtained at a cost of an order of magnitude less, then it can be applied in many situations in large quantities in field. For example, a machine tool or a positioning stage can have several sensors installed at strategic locations and combined measurement results can be used to track machine deformations or position errors in multiple directions due to thermal or load effects in real time. Such information can lead to further improvement of process accuracy. This present invention describes a small sized precision displacement sensor at sub-micron accuracy level with a cost of a fraction of those of existing commercial devices.

### SUMMARY OF THE INVENTION

This present invention describes a precision contact displacement sensing device for measuring a micro-displacement of a target surface with a measurement range from a few micrometers to hundreds of micrometers and a measurement resolution on the order of 0.01 to 1 micrometer and a measurement accuracy also on the order of 0.01 to 1 micrometer. The basic concept is to apply a mechanical mechanism to magnify a sub-micron displacement to be measured by about 100 times so that the magnified displacement becomes within the measurement range of an existing low cost displacement sensor. By making a mechanical mechanism capable of maintaining its magnification ratio with reasonable repeatability, the existing low-cost displacement sensor, in combination with the mechanical mechanism, can measure the micro-displacement to about 1/100 th of its own resolution and accuracy.

Based on the above concept, the precision contact displacement sensing device comprises a displacement magnifying mechanism for magnifying the micro-displacement. The displacement magnifying mechanism comprises an integral structure mounted on a base. The integral structure is capable of elastic deformation and has a geometric layout such that when a contact force, or a change of contact force, is exerted to one place (or spot or location) on the integral structure (called contact place thereafter for convenience) the structure deforms elastically and results in a displacement of the contact place as well as a displacement of another place (called measurement place thereafter) on the integral structure and magnitude of the displacement of the measurement place is equal to magnitude of the displacement of the contact place multiplied by a magnification ratio, which is designed to be on the order of about 100.

The precision contact displacement sensing device also comprises an artifact (called contact artifact thereafter) in contact with the target surface. The artifact transmits the micro-displacement of the target surface to the contact place on the integral structure in full amount.

That is, the displacement of the contact place is equal to the micro-displacement to be measured. As a result, the magnitude of the displacement of the measurement place, due to the magnification of the deformation of the integral structure, is a magnification of the magnitude of the micro-displacement by the designed magnification ratio. In other words, the micro-displacement to be measured is magnified by a factor of about 100 at the measurement place, assuming the magnification ratio is set to be about 100.

The precision contact displacement sensing device also comprises a non-contact displacement sensor unit, mounted to the same base as the integral structure, for measuring the magnified displacement at the measurement place. For the targeted measurement range of the precision contact displacement sensing device from a few micrometers to hundreds of micrometers and a measurement resolution/accuracy between 0.01 to 1 micrometer, as set forth previously, the corresponding micro-displacement to be measured could be on the scale of 1 to 100 micrometer. Because the micro-displacement is magnified by a factor of about 100, the scale of the magnified displacement is now between 0.1 to 10 mm (or equivalently 100 to 10,000 micrometers) and the accuracy/resolution is between 1 to 100 micrometer. This range of accuracy and resolution can be achieved by an existing low cost displacement sensor, such as a Hall effect sensor. Thus, the combination of the existing low cost displacement sensor with the mechanical displacement magnifying mechanism enables the existing low cost displacement sensor to measure micro-displacements with sub-micrometer resolution and accuracy.

The integral structure can be a structure fabricated from a monolithic piece of solid material or an assembly of parts joined into an integral solid structure. Therefore, there is no mechanical contact with relative motion between any parts of the structure. The magnification is purely due to the geometric layout and the elastic deformation of the structure. This ensures consistency and good repeatability of the magnification mechanism.

One preferred embodiment of the integral structure is a system of lever structures connected in cascaded stages. Each lever structure includes a base frame, an arm (beam) and a flexural hinge connecting the arm to the base frame as fulcrum. Thereby a lever structure is an integral solid structure and the elastic deformation of the flexural hinge allows the lever to move. The base frames are joined together as an integral solid and fixed to the base of the integral structure. The output end (load end) of the arm of one lever structure is connected and coupled to the input end (effort end) of the arm of the lever structure of the next stage by a flexural coupler that transmit arm displacement and accommodate relative motion between the two adjacent arms. Therefore, magnified displacement in a lever structure in one stage drives another lever structure in the next stage and is amplified further.

To obtain an overall magnification of about 100, 2 or 3 stages of lever structure can be used. If 2 stages are used, then the magnification ratio of each lever structure can be about 10. If 3 stages are used, then the magnification ratio of each lever structure can be between 4 and 5.

The lever structures can be disposed with one lever structure on top of another and with the planes of motion of the arms all on a same plane. The lever structures can also be disposed side by side with all arms in parallel and with the plane of motion of each arm different but parallel to each other. In order to have a compact form factor and small characteristic size, it is preferred to align adjacent lever structures with the output ends of the arms pointing to opposite directions. When the lever structures are arranged side by side, it is preferred for the flexural coupler have two perpendicular flexural sections, one for accommodating relative rotations and one for minute relative translations between two adjacent arms.

In order to minimize loss of magnification and to maximize displacement transmission efficiency, it is preferred to arrange the geometric layout of the integral structure such that the contact force results in mainly bending and/or tension in the flexural hinges and the flexural couplers during operation and compression or shearing forces perpendicular to the axes of rotation of the flexural sections of these flexural connecting parts are avoided. This also helps maintaining repeatability of the functions of the mechanism.

Another embodiment of the integral structure is a system of bridge-type mechanical amplifiers connected in cascaded stages. A bridge-type mechanical amplifier includes a pair of bridge structures. Each bridge structure includes a rigid middle section with two flexural foils attached at two sides at an angle, forming a basic bridge geometric. To rigid end sections are attached to the two ends of the bridge geometric. The two bridge structures are joined in a symmetric form with the two end sections of one bridge structure attached to the two end sections of the other bridge structure, with the arch spaces of the bridges in between. Preferably, one bridge structure of the pair is fixed to the base at its middle section and an input force (displacement) acts on the inner side of the middle section of the other bridge structure, creating tensions in the structures, for reasons described previously. The output end is on one of the two joined end sections. For transmitting a displacement from one stage to the next stage, a flexural coupler connects the output end to the input middle section. In the bridge-type mechanical amplifier, the motion direction of the input is perpendicular to that of the output. Therefore, the amplifiers of adjacent stages are also disposed in perpendicular directions with an output end of one stage pointing to the input middle section of the next stage.

The contact artifact can be an object of high hardness with a pointing profile. A fabricated ball of zirconia, ruby, or alumina can be used. The ball can be fixed to the contact place on the integral structure directly.

When the target surface is moving relative to the micro-displacement sensing device with its major motion in directions perpendicular to the direction of motion of the micro-displacement of the contact artifact, it is preferred to provide a mechanism to avoid possible effects of the major motion to the magnification mechanism. Therefore, a contact relay mechanism can be applied to ensure that the contact artifact and the contact place only moves in the designed direction. The contact artifact can be set on a hard seat at the unsupported end of a thin but wide flexural cantilever beam so that the contact artifact basically can only move in direction of deflection of the cantilever beam. A second contact artifact is fixed to the contact place on the integral structure directly. The flexural cantilever beam can be fixed to a casing, which is attached to the base, and the hard seat can be brought in contact with the second contact artifact with a slight preload so that the target surface, the first artifact with the hard seat and the second contact artifact are always kept in contact. This way, the micro-displacement of the target surface can be transmitted fully to the contact place on the integral structure.

A preferred sensor unit includes a Hall sensor on the base and a magnet on the measurement place of the integral structure facing the sensing surface of the Hall sensor.

The sensing device also includes a casing covering the magnifying mechanism and the sensor unit for protection purpose.

According to above contents, the system of the present invention can have at least one of the following advantages: low cost, compact, precision as commercial micro-displacement sensors, being able to output an electrical signal and easy to be applied for control and monitoring purpose.

### BRIEF DESCRIPTION OF THE DRAWINGS

The structure, operating principle and effects of the present invention are described in details by the following drawings.

FIG. 1 is a comparison of commercially available micro-displacement sensors in performances and prices.

FIG. 2 explains the basic principle of the present invention with specific dimensional numbers as an example.

FIG. 3 depicts an example of a single lever structure according to an embodiment of the present invention.

FIG. 4 shows a typical flexural bearing in integral form (monolithic form).

FIG. 5 explains the assembly of a displacement magnifying mechanism of 3 stages of lever structure in exploded view according to an embodiment of the present invention.

FIG. 6 depicts an assembled displacement magnifying mechanism of 3 stages of lever structure according to an embodiment of the present invention.

FIG. 7 depicts a full assembly of the low-cost micro-displacement sensor including a displacement magnifying mechanism based on 3 stages of lever structure and a Hall sensor.

FIG. 8 depicts the arrangement of a contact artifact mounted directly to the contact position of the integral structure and the opening on the device casing with a sealing film in sectional view from the side according to an embodiment of the present invention.

FIG. 9 depicts an assembled displacement magnifying mechanism of 2 stages of lever structure with a Hall sensor according to an embodiment of the present invention.

FIG. 10 depicts a contact relay mechanism in sectional view from the side according to an embodiment of the present invention.

FIG. 11 depicts an assembled displacement magnifying mechanism of 2 stages of bridge-type mechanical amplifier with a Hall sensor according to an embodiment of the present invention.

FIG. 12 (a), (b) show example prototypes according to embodiments of the present invention. FIG. 12 (c) shows measurement results.

FIG. 13 depicts a design of a localized magnetic shielding according to an embodiment of the present invention.

FIG. 14 depicts a first example design of a mechanically balanced lever structure, using the 2-stage magnifying mechanism of FIG. 9 as example, according to an embodiment of the present invention.

FIG. 15 depicts a second example design of a mechanically balanced lever structure with a lever arm comprising a balanced shape, according to an embodiment of the present invention.

### DETAILED DESCRIPTION OF THE PREFERRED EMBODIMENTS

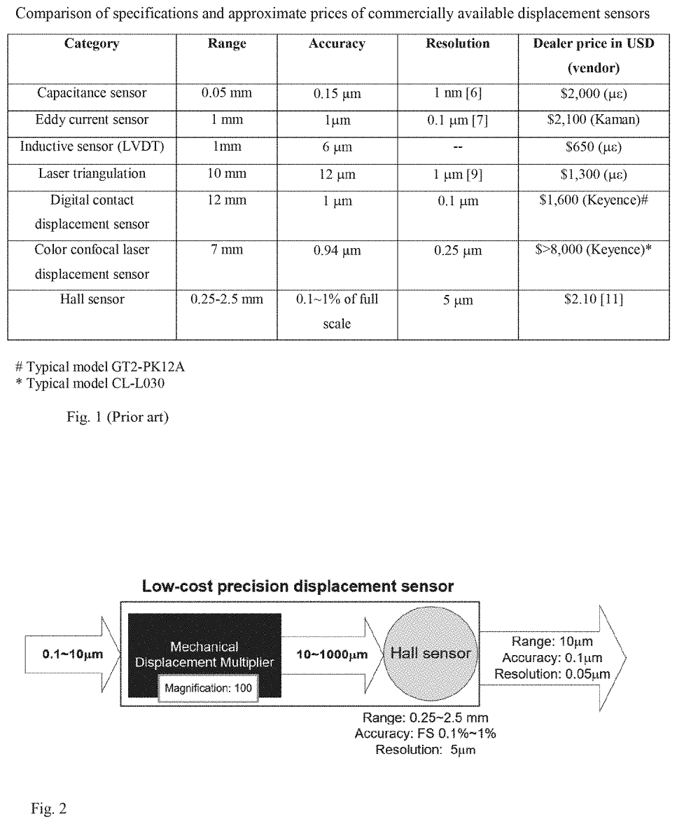

From FIG. 1, we see that Hall sensor has a significantly low cost but with a measurement resolution of about 5 μm. It has an accuracy of about 0.1-1% of full scale and a range of 0.25-2.5 mm. That is, for a measurement range on the order of 1000 μm and a resolution/accuracy of 1-5 μm , Hall sensor is a very cost-effective choice. Now, for measuring a displacement down to 0.1 μm, if we can magnify this tiny displacement by a factor of, say, 100 then we'll be measuring 10 μm, which falls well within Hall sensor's capability. That is, if a magnification mechanism can be devised to reliably magnify sub-micron displacements with good repeatability, then a Hall sensor can be used to resolve a micro-displacement of 0.1 μm with a full range of 10 μm, while the Hall sensor itself is measuring displacements in a full range of 1 mm with a resolution of 10 μm. The idea is shown in FIG. 2. Such a mechanical magnification mechanism can be made small with low cost and, combined with a Hall sensor, or other sensor capable of similar measurement range and accuracy and resolution, a low cost precision displacement sensor can be made.

One preferred embodiment of the mechanical displacement magnifying mechanism features an integral structure of lever structures connected in cascaded stages. Magnified displacement in a lever structure in one stage drives another lever structure in the next stage and is amplified further.

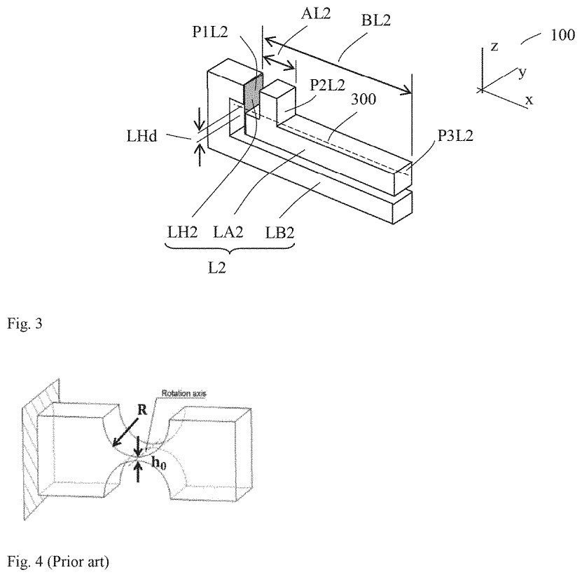

FIG. 3 depicts an example of a single lever structure, which includes a base frame LB2, an arm (beam) LA2 and a hinge LH2 that connects the arm to the base frame. For convenience of later description, this lever structure is referred to as the 2nd lever L2. In a practical implementation, the base frame and the arm can be made of a metal or any other sturdy material.

The hinge can be in the form of a foil spring, such as a spring steel foil, as illustrated in FIG. 3. The foil spring is attached to a base mounting face P1L2 on the base frame and to one end of the arm. The amounting can be by screw or by joining such as brazing or soldering or glue. A small section of the foil spring (LHd) is left “bare”, that is, without contact to either the arm or the base frame, in order to facilitate the hinge function. The arm and the base frame can also be made from a single piece of material with a flexural joint in between as the hinge in integral form. FIG. 4 shows a typical flexural joint in integral form, which is also called a monolithic flexural joint or bearing in industry. The principle of flexural bearing or joint in monolithic form or foil spring form (or called clamped flat spring) can be seen in Slocum, A. H., Precision Machine Design, Prentice Hall, New Jersey, 1992, Chapter 8, section 8.6, which is incorporated herein by reference. By either way, the lever structure is made into an integral body with no sliding contact and the arm rotates only by elastic bending of the hinge. The arm includes a protruded feature with a second mounting face P2L2, which is parallel to the first mounting surface P1L2. When the protruded feature on the arm is pushed downward (i.e., toward −z direction, referring to coordinate frame 100), downward displacement at the second mounting face P2L2 is amplified at the end of the arm at a third mounting face P3L2 by a factor of BL2/AL2, the ratio of the distances from the third mounting face P3L2 and the second mounting face P2L2 to the base mounting face P1L2. For the purpose of magnifying displacement, the point at the second mounting face P2L2 can be viewed as the input end (i.e., the effort end by common terms used for a lever) of the arm of the lever and the third mounting face P3L2 as the output end (i.e., the load end by common terms used for a lever) of the arm.

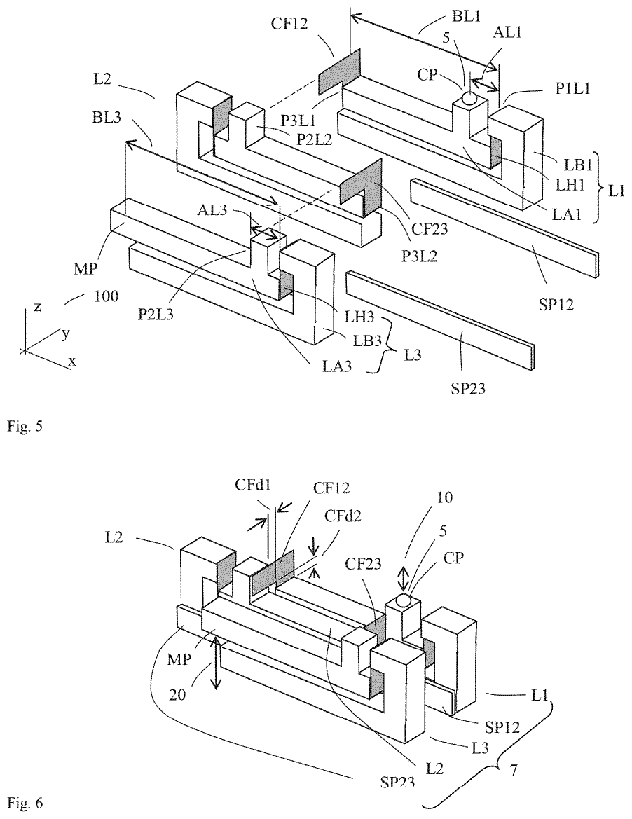

To magnify a tiny displacement by two orders of magnitude, 2 or 3 stages of lever structures are connected in cascade side by side in parallel orientations by using a flexural coupling foil (that is, the flexural coupler) between adjacent lever structures. FIG. 5 explains the assembly of a magnification mechanism of 3 stages of lever structures in exploded view. The 3 lever structures are of basically similar configuration as the one depicted in FIG. 3. In this example, the lever structures are disposed side by side with all arms in parallel and with the plane of motion of each arm different but parallel to each other. The first stage lever L1 includes a base frame LB1, an arm LA1 and a hinge LH1. The arm LA1 also has a protruded feature as the contact place CP, onto which a ball, for example, made of Zircon, is mounted as the contact artifact 5 as the input point, i.e., the input end (the effort end), of the arm LA1. The magnification ratio from the contact place CP to the end of the arm P3L1, which is the output end (the load end) of the arm LA1, is BL1/AL1. In FIG. 5, lever L1 is oriented with the output end P3L1 of the arm LA1 pointing to −x direction.

The second stage lever, L2, already described with FIG. 3, is placed in parallel relative to lever L1 but oriented with its output end of arm P3L2 pointing toward +x direction. That is, in order to have a compact form factor and small characteristic size, adjacent lever structures are aligned with the output ends of the arms pointing to opposite directions. Further, the second mounting face P2L2 of the arm LA2 is aligned to the end face P3L1 of the arm LA1 such that a flexural foil CF12 couples lever L1 and lever L2 at the two faces. The lower portion of the “F”-shaped foil is mounted to the arm LA1 at its end face P3L1 and part of the upper portion is mounted to the second mounting face P2L2 of the lever L2. Thus, the displacement at the output end of the arm LA1 can be transmitted to the input end of the arm LA2 of lever L2.

The third stage lever, L3, is basically similar to lever L1, with a base frame LB3, an arm LA3 and a hinge LH3. Lever L3 is oriented with its output end of arm pointing toward −x direction. The arm LA3 also has a protruded feature with a second mounting face P2L3, which is aligned to the end face P3L2 of the arm LA2. Similarly, the lower portion of a “I”-shaped foil flexural foil CF23 is mounted to the arm LA2 at its end face P3L2 and part of the foil's upper portion is mounted to the second mounting face P3L2 of the lever L2. Thus, the displacement at the output end of the arm LA2 can be transmitted to the input end of the arm LA3 of the lever L3. The magnification ratio from position P3L2 to a measurement place MP near the end of the arm LA3 is BL3/AL3.

The 3 lever structures are assembled side by side together with a spacer stripe (SP12 and SP23) between adjacent lever structures to prevent unwanted sliding contact between the arms. FIG. 6 depicts the assembled magnifying mechanism of the 3 stages of lever structure. The 3 cascaded lever structures constitute the integral structure 7 capable of elastic deformation as described in Summary of the Invention. The contact artifact 5, a contact ball in this case, is set to the place CP on lever L1 directly. A tiny displacement at the contact place CP is magnified at the measurement place MP by a cascaded ratio of:

Total theoretical magnification=(BL1/AL1) (BL2/AL2) (BL3/AL3) (1)

Arrows 10 and 20 indicate directions of the input micro-displacement and of the output magnified displacement of the assembly respectively. Assuming the magnification of each lever structure is 5, the total theoretical magnification is then 125, two orders of magnitude amplification.

In order to achieve good results, all arms should be of lightweight construction. Dimensions of all hinges should be made to have maximum stresses within endurance limit in the full operation range of the system. Each coupling foil (CF12 and CF23) should be mounted with two “bare” sections, that is, without any other material or structure one either side of the sections. As depicted in FIG. 6, on coupling foil CF12, a horizontal bare section CFd2 above lever L1 and a vertical bare section CFd1 to the side of lever L2. Same for coupling foil CF23 (details not shown). The reason for this feature is that there are not only rotational relative motions between adjacent arms, that is, arms of lever structures in successive stages, but also small linear relative motions when the magnifying mechanism operates. These bare sections can accommodate these relative motions and facilitate motion transmission from one stage to the next. Further, to minimize loss and maximize displacement transmission efficiency, the geometric layout of the cascaded lever structures is arranged such that a contact force results in mainly bending and/or tension in the flexural hinges and the flexural couplers during operation and compression or shearing forces perpendicular to the axes of rotation of the flexural sections of these flexural connecting parts are basically avoided. As shown by the example depicted in FIG. 5 and FIG. 6, when a contact force acts along arrow 10 toward the contact place CP, the arm LA1 experiences a downward force. Because, on the arm LA1, the flexural hinge LH1 extends upward to the fulcrum at base mounting face P1L1 of the based frame LB1 and the flexural coupler CF12 also basically extends upward toward the load at the next stage, both the flexural hinge and the flexural coupler are basically exerted with tensile forces to counter the downward force exerted on the arm and with bending moments due to slight rotation of the arm. Similar situations can be seen in other flexural hinges (LH2, LH3) and the other flexural coupler (CF23). There is basically no compressive or shearing force on the flexural sections in the hinges and couplers. This feature also helps maintaining repeatability of the functions of the mechanism.

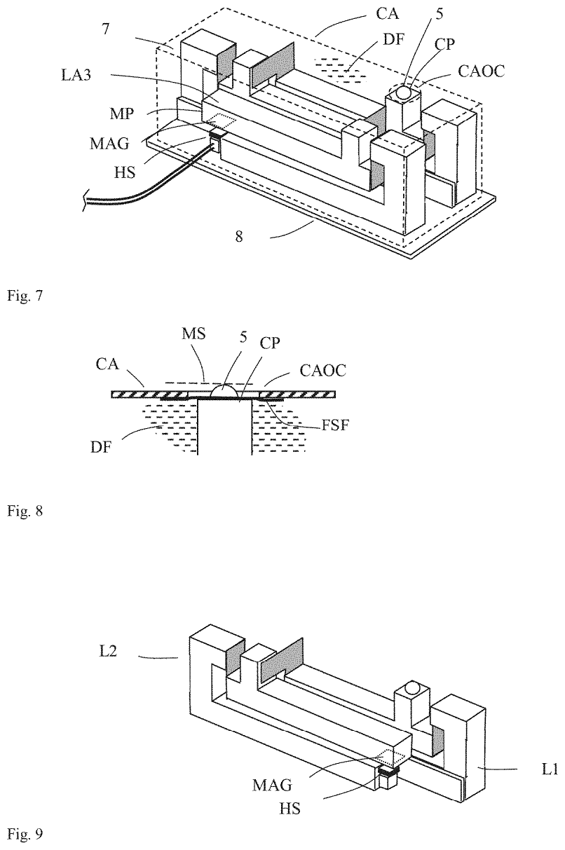

The magnified displacement at MP can then be measured by a Hall sensor HS. FIG. 7 depicts a full assembly of the low-cost micro-displacement sensor based on the displacement magnifying mechanism applying cascaded lever structure and a Hall sensor. The displacement magnifying mechanism 7 is mounted to the base 8. The Hall sensor HS is also fixed to the base 8. The magnet pad MAG is attached to the bottom of the arm LA3. The assembly is packaged within a casing CA.

Because the contact artifact 5 at the contact place CP must be exposed above the casing, an opening configuration CAOC as shown in FIG. 8, in sectional view, can be applied. A thin soft film FSF, of polymer for example, glued to the peripheral of the ball and the rim of the opening hole can act as a membrane seal with minimum effect to the responsive force of the displacement sensor at contact place CP. MS indicate the target surface, of which displacement is to be measured, in contact with the ball.

The interior of the casing can contain a dampening fluid DF, in case the lever structures, especially the last stage (e.g. L3), become sensitive to vibration caused by external effects other than displacement at the contact artifact 5. The dampening fluid can reduce or eliminate these vibration noises.

If lever structures of magnification ratio of 10 are used, then two stages are enough to create 10×10=100 times magnification. FIG. 9 illustrates the idea of a 2-stage system.

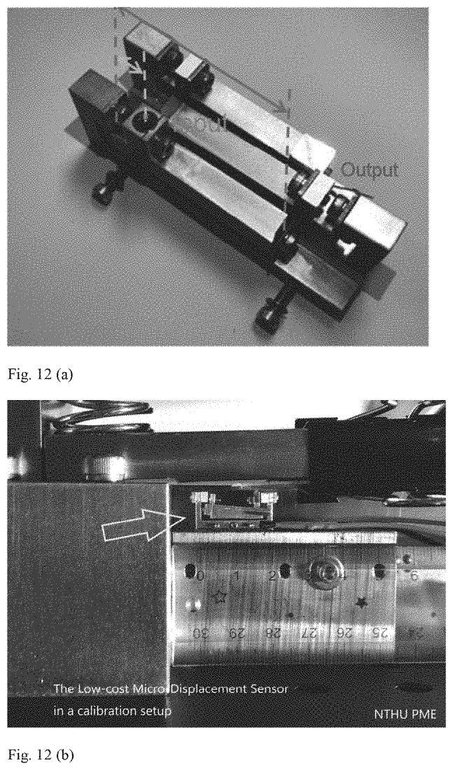

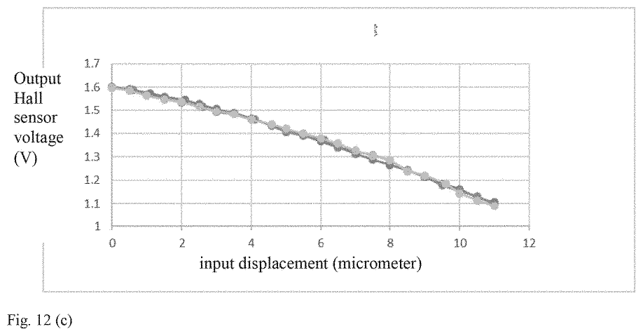

Two prototypes of the low cost micro-displacement sensor were built using lever structure magnifying mechanism of cascaded lever structures made from aluminum and steel foil springs and using Honeywell SS495A Hall sensor with a tape magnet for output reading. FIG. 12 (a) illustrates a 3-stage prototype of about 80 mm long. FIG. 12 (b) illustrates a 2-stage prototype of 20 mm long in a calibration setup. Both having a magnification ratio of about 125.

Test measurements were calibrated and compared with results from a precision eddy current sensor. FIG. 12 (c) shows measurement results of output voltage in relation to input micro-displacement of the prototype of FIG. 12 (b). FIG. 12 (c) shows that for input micro-displacement in the range from 0 to about 11 micrometer, which is measured using a precision eddy current sensor, the output voltage is from 1.6 to 1.1 V. A calibration can therefore be made to correlate an output voltage to a corresponding micro-displacement. Data analysis shows an accuracy of 0.6 micrometer and resolution of 0.1 micrometer. Thus, this prototype represents an example of the precision contact displacement sensing device with a measurement range of a few micrometers (0-11 micrometer for the prototype) and a measurement resolution/accuracy on the order of 0.01 to 1 micrometer (0.1/0.6 micrometer for the prototype), as set forth in the beginning of this specification.

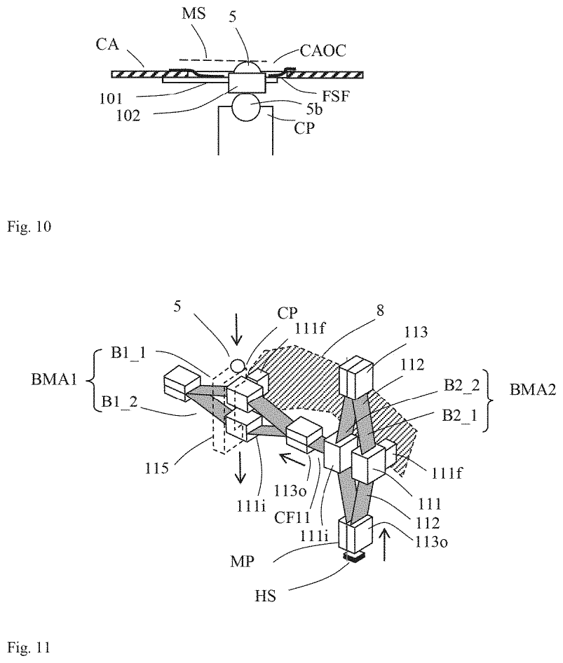

When the target surface is moving relative to the micro-displacement sensing device with its major motion in directions perpendicular to the direction of motion of the micro-displacement of the contact artifact, it is preferred to provide a mechanism to avoid possible effects of the major motion on the magnification mechanism. A preferred approach is to use a contact relay mechanism to restrict the contact artifact and the contact place on the displacement magnifying mechanism to move only in the designed direction. FIG. 10 illustrates an example of contact relay mechanism that comprises a thin but wide flexural cantilever beam 101 with one end attached to a fixed support, such as the casing CA, and a hard seat 102 at the unsupported end. The contact artifact 5 can be fixed onto the hard seat 102 so that the contact artifact basically can only move in direction of deflection of the cantilever beam. A second contact artifact 5b is fixed to the contact place on the integral structure directly. The flexural cantilever beam can be fixed to a casing CA, which is attached to the base 8, and the hard seat 102 can be brought in contact with the second contact artifact 5b with a slight preload so that the target surface, the contact artifact 5 with the hard seat 102 and the second contact artifact 5b are always kept in contact. This way, the micro-displacement of the target surface can be transmitted fully to the contact place CP on the integral structure.

Although the magnification mechanism described above is an assembly from individual lever structures, the basic concept can also be implemented by making a similar but integral structure of multiple levers by injection molding of one or more polymeric materials.

Another embodiment of the integral structure is a system of bridge-type mechanical amplifiers connected in cascaded stages. The principle of the bridge-type mechanical amplifier can be seen in Juuti et al., “Mechanically amplified large displacement piezoelectric actuators”, Sensors and Actuators A 120 (2005) 225-231, which is herein incorporated by reference. FIG. 11 depicts 2 modified bridge-type mechanical amplifiers connected in cascade. As depicted in FIG. 11, a modified bridge-type mechanical amplifier (BAM2, for example) includes a pair of bridge structures (B2_1 and B2_2). Each bridge structure includes a rigid middle section 111 with two flexural foils 112 attached at two sides at an angle, forming a basic bridge geometric.

Two rigid end sections 113 are attached to the two ends of the bridge geometric. The two bridge structures are joined in a symmetric form with the two end sections of one bridge structure attached to the two end sections of the other bridge structure, with the arch spaces of the bridges in between. In the stage 1 bridge-type mechanical amplifier BAM1, one bridge structure of the is fixed to the base 8 at its middle section 111f. The input force (displacement) acts on the other middle section 111i of the other bridge structure, through the contact place CP on a bracket 115. The output end is on one of the two joined end sections 113o. For transmitting a displacement from one stage to the next stage, a flexural coupler CF11 connects the output end 113o to the input middle section 111i of the next stage BAM2. In the bridge-type mechanical amplifier, the motion direction of the input is perpendicular to that of the output. Therefore, the amplifiers of adjacent stages are also disposed in perpendicular directions with an output end of one stage pointing to the input middle section of the next stage.

The present invention disclosed herein has been described by means of specific embodiments. However, numerous modifications, variations and enhancements can be made thereto by those skilled in the art without departing from the spirit and scope of the disclosure set forth in the claims.

For example, although the lever structures described in the examples all have their fulcrum position at one end of the arm (beam), lever structures having the fulcrum positioned between the input end and the output end can also be used and can be cascaded by following the teaching from the above disclosure.

It should also be noted that the magnification ratio of the mechanical magnifying mechanism does not need to be constant over the full measurement range. Therefore, the non-linearity of FIG. 12 (c) does not affect the function of the sensor, as long as the output repeatability corresponding to a fixed input is good. It should further be noted that although a magnification ratio of about 100 is used in the descriptions of the current invention the magnification ratio can be adjusted according to need based on the cascaded ratio of total theoretical magnification described above. For example, as described previously, the prototype of FIG. 12 (b) is a 2-stage system with a magnification ratio of about 125 and is an example with a measurement range of a few micrometers (0-11 micrometer for the prototype) and a resolution/accuracy on the order of 0.01 to 1 micrometer (0.1/0.6 micrometer for the prototype). If the total magnification ratio is changed to 25 (=5×5) and a measurement range is increased to 100 micrometer, then the magnified maximal displacement will be 2500 micrometer (or 2.5 mm), which is still within a Hall sensor's measurement range.

Because the Hall sensor uses magnetic field for measurement, it is preferred for the casing to contain a magnetic shielding layer to filter out possible externa magnetic disturbances. A “Mu metal” sheet or a sheet of an alloy of nickel, iron and molybdenum can serve the purpose. The sheets can be laid over the outside or inside surfaces of the casing CA (FIG. 7). Alternatively, or in addition, shielding foils can be applied localized around the Hall sensor and the magnet.

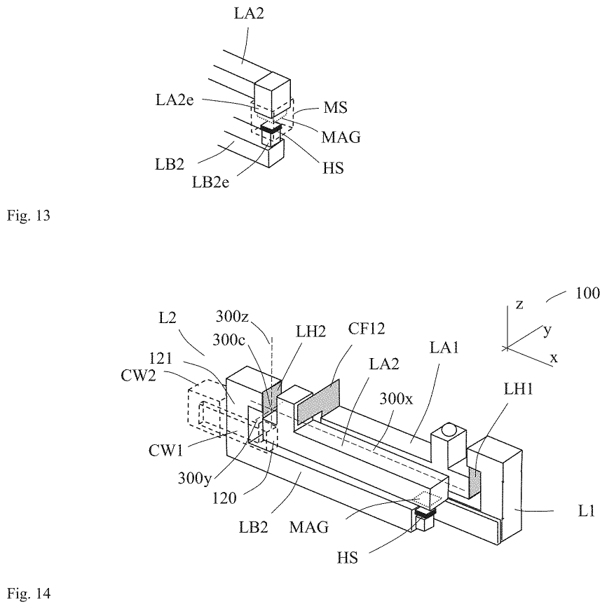

Using the 2-stage mechanism of FIG. 9 as an example, FIG. 13 depicts such a localized shielding design. The end of the lever arm LA2 includes a short post LA2e protruding toward the location of the Hall sensor HS. The magnet MAG sits on the post LA2e. Similarly, the end of the base frame LB2 includes a small post LB2e protruding toward the location of the magnet MAG. The Hall sensor sits on this small post. The two short post structures allow a magnetic shielding foil

MS to be wrapped in tubular form around both the Hall sensor and the magnet and to be attached to either one of the two short posts, while small relative displacement between the Hall sensor and the magnet is not affected. This localized magnetic shielding structure is one of the two improvements over the subject matters filed earlier.

Preferably, a mechanically balanced lever arm can be applied to at least one of the levers in the multiple-lever displacement magnifying mechanism or in a single lever displacement magnifying mechanism. Using the 2-stage mechanism of FIG. 9 as an example to explain again, due to the requirement of magnification ratios on the levers, both lever arms LA1 and LA2 have more material toward one side of their hinges. Therefore, the centers of mass of the lever arms are away at a distance from the hinges. As a result, vibration could cause undesirable oscillation of the lever, especially for lever arm LA2, which is supported only from one end. Further, when the device is oriented in different directions, the “null position” of the displacement magnifying mechanism could be different. For example, at the orientation shown in FIG. 9, with the gravity in −z direction, the weight of the arm LA2 will give a shortened null distance between the Hall sensor HS and the magnet MAG. If the device is flipped upside down, or making the gravity in +z direction, then the null distance between the Hall sensor HS and the magnet MAG will be increased. This makes the calibration between the input micro-displacement and the Hall sensor output complicated.

The solution to the above issue is to balance the lever arm mechanically to move the center of mass of the arm to or close to the hinge. The mechanically balanced lever structure comprises a balanced arm shape and a counter-weight structure that places the center of mass of the lever arm assembly at or close to the hinge. Thus, external disturbances due to vibration can be reduced and the displacement sensing device can be operated at basically arbitrary orientation. FIG. 14 depicts a first example design of a mechanically balanced lever structure, using the 2-stage magnifying mechanism of FIG. 9 as example. The added counter-weight structure includes a connector CW1 and a ballast CW2. The connector CW1 is attached to the side of the arm at 120 so that the ballast can circumvent the post 120 and be placed to the back of the post 120. This arrangement can move the center of mass of the whole arm structure, including the added counter-weight structure, to a position at or close to the hinge LH2.

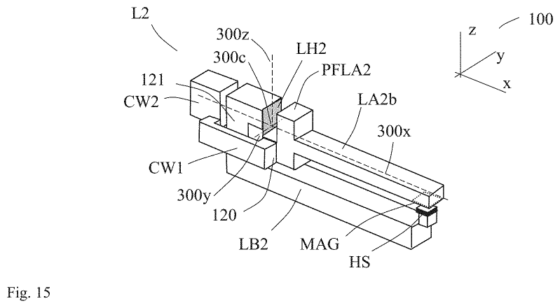

FIG. 15 depicts a second example design of a mechanically balanced lever structure, using lever L2 of FIG. 9 as example again. First, referring to FIG. 14, wherein the center of the flexural portion of the hinge foil LH2 is marked as 300c and three axes passing the center are also illustrated, 300x, 300y and 300z, with the shape of the arm LA2, which comes from FIG. 9, most material of the arm LA2 (excluding the counter-weight structure CW1 and CW2) is below the center line 300x. Therefore, in order to move the mass center of the arm and counter-weight structure assembly to the center of the hinge 300c, the counter weight CW2 needs not only enough mass, giving a shorted counter arm length, but also to be placed at a higher z position. Or else the resulted mass center may locate on axis 300z but not necessarily at center 300c. FIG. 15 depicts a lever arm LA2b with a balanced shape with about equal material above and below axis 300x, which eases the positioning of the counter weight CW2.

In general, the shape (mass distribution) of the lever arm and the counter-weight structure can be designed such that the mass center of the combined assembly of the arm and the counter-weight structure is close to, and preferably at, the center of the hinge 300c.

Similar arm shape design and counter-weight arrangements can also be applied to lever arm LA1, although arm LA1 is supported at two ends by the hinge LH1 and the flexural coupler CF12 and is less affected by either vibration or orientation problem.

Although the descriptions so far focus on displacement magnifying mechanism of 2 or 3 stages of lever structures with a total magnification of about 100, the mechanisms and techniques described in the current invention can be applied to a wide range of magnification and combination. Especially, with the mechanically balanced lever structure, a single stage lever with a large magnification ratio can be used with minimal concern about vibration disturbance or operating orientation. Such a mechanism will look like the mechanism depicted in FIG. 15, with the contact point placed on top of the protruded feature PFLA2. For example, a micro-displacement sensing device using a single stage lever structure of a magnification ratio of 25 can be designed and, using a Hall sensor with the numbers from FIG. 2, achieve a measurement range of 100 μm with accuracy 1 μm and resolution 0.2 μm.

What is claimed is:

1. A precision contact displacement sensing device for measuring a micro-displacement of a target surface with a measurement range from a few micrometers to hundreds of micrometers, the device comprising:
a displacement magnifying mechanism, the mechanism comprising an integral structure mounted on a base, the integral structure being capable of elastic deformation and having a geometric layout such that a displacement at a contact place on the integral structure results in a displacement at a measurement place also on the integral structure and magnitude of the displacement of the measurement place is equal to magnitude of the displacement of the contact place multiplied by a magnification ratio;
a contact artifact in contact with the target surface for receiving the micro-displacement of the target surface, the contact artifact being disposed on a contact relay mechanism that restricts the contact artifact to move only in directions of the micro-displacement to be measured;
a second contact artifact fixed onto the contact place on the integral structure, the contact relay mechanism being in contact with the second contact artifact; and,
a non-contact displacement sensor unit for measuring the displacement of the measurement place, the sensor unit having a measurement resolution on the order of 1 to 5 micrometer and a measurement accuracy of 1 to 10 micrometer, the sensor unit being capable of outputting an electric signal correlated to the measured displacement of the measurement place.

2. The device of claim 1, wherein
the displacement magnifying mechanism comprising a plurality of lever structures connected in cascaded stages as the integral structure, each stage of the cascaded stages comprising one of the lever structures respectively, each of the lever structures including a base frame, an arm and a flexural hinge connecting the arm to the base frame as fulcrum, the base frames of the cascaded stages being joined together as an integral solid and fixed to the base;
the contact relay mechanism comprising a hard seat and a cantilever beam that has one end attached to a fixed support and another end unsupported, the hard seat being fixed to the unsupported end of the cantilever beam, the contact artifact being fixed onto the hard seat, the cantilever beam providing a preload for the hard seat to be in contact with the second contact artifact;
the contact place being on input end of the arm of the lever structure of a first stage of the cascaded stages, output end of the arm of the lever structure of the first stage being connected and coupled to input end of the arm of the lever structure of a next stage of the cascaded stages adjacent to the first stage by a flexural coupler that transmits displacement of output end of the first stage to input end of the next stage, the measurement place being on output end of the arm of the lever structure of a last stage of the cascaded stages; and,
the non-contact displacement sensor unit comprising a Hall sensor on the base and a magnet on the measurement place.

3. The device of claim 2, wherein
the lever structures being disposed side by side with all the arms in parallel and with plane of motion of each arm different from but parallel to each other;
the arms of the lever structures of every two successive stages of the cascaded stages being aligned with their output ends pointing to opposite directions;
the flexural coupler comprising two perpendicular flexural sections, one flexural section for accommodating rotational relative motions between two adjacent the arms of the lever structures of two successive stages of the cascaded stages when the device works and another flexural section for accommodating small linear relative motions between two adjacent the arms of the lever structures of two successive stages of the cascaded stages during operation of the precision contact displacement sensing device.

4. The device of claim 3, wherein
The cascaded stages of the lever structures comprising a geometric layout such that a contact force acting on the contact artifact results in basically tension and bending in the flexural hinges and the flexural couplers.

5. The device of claim 2, wherein at least the arm of the lever structure of the last stage of the cascaded stages comprises a mechanically balanced structure with its mass center close to center of its flexural hinge.

6. The device of claim 5, wherein mechanically balanced structure comprises a connector and a ballast connected to the arm as a counterweight structure.

7. The device of claim 6, further comprising a local magnetic shielding layer shielding the Hall sensor and the magnet from external magnetic disturbances.

8. A precision contact displacement sensing device for measuring a micro-displacement of a target surface with a measurement range from a few micrometers to hundreds of micrometers, the device comprising:
a displacement magnifying mechanism, the mechanism comprising a plurality of lever structures connected in cascaded stages as an integral structure mounted on a base, each stage of the cascaded stages comprising one of the lever structures respectively, each of the lever structures including a base frame, an arm and a flexural hinge connecting the arm to the base frame as fulcrum, the base frames being joined together as an integral solid and fixed to the base;
a contact place on input end of the arm of the lever structure of a first stage of the cascaded stages, output end of the arm of the lever structure of the first stage being connected and coupled to input end of the arm of the lever structure of a next stage of the cascaded stages adjacent to the first stage by a flexural coupler that transmits displacement of output end of the first stage to input end of the next stage;
a measurement place on output end of the arm of the lever structure of a last stage of the cascaded stages;
the lever structures being disposed side by side with all the arms in parallel and with plane of motion of each arm different from but parallel to each other, the arms of the lever structures of every two successive stages of the cascaded stages being aligned with their output ends pointing to opposite directions;
the flexural coupler comprising two perpendicular flexural sections, one flexural section for accommodating rotational relative motions between two adjacent the arms of the lever structures of two successive stages of the cascaded stages when the device works and another flexural section for accommodating small linear relative motions between two adjacent the arms of the lever structures of two successive stages of the cascaded stages during operation of the precision contact displacement sensing device;
thereby a displacement at the contact place resulting in a displacement at the measurement place and magnitude of the displacement of the measurement place is equal to magnitude of the displacement of the contact place multiplied by a magnification ratio.

9. The device of claim 8, further comprising
a contact artifact in contact with the target surface for receiving the micro-displacement of the target surface;
a contact relay mechanism that restricts the contact artifact to move only in directions of the micro-displacement to be measured.
